(19) United States
(12) Patent Application Publication
(10) Pub. No.: US 2025/0370422 A1
(43) Pub. Date: Dec. 4, 2025

(54) METHOD FOR OBTAINING DIFFERENT ADDRESSES BY CHANGING INTERNAL LOGIC VALUES OF CHIP THROUGH LIGHT

(71) Applicant: Shenzhen HSG Electronics Co., LTD, Shenzhen (CN)

(72) Inventors: WEI SHEN, Shenzhen (CN); BO GUAN, Shenzhen (CN); ZONGZE YE, Shenzhen (CN)

(21) Appl. No.: 18/764,685

(22) Filed: Jul. 5, 2024

(30) Foreign Application Priority Data
May 28, 2024 (CN) 202410673624.3

(51) Int. Cl. G05B 19/05; G05B 19/07

(52) U.S. Cl. CPC G05B 19/054; G05B 19/07; G05B 2219/1103; G05B 2219/1113

(57) ABSTRACT

Disclosed is a method for obtaining different addresses by changing internal logic values of a chip through light, the light containing address information is irradiated on a LED lamp bead, and then is transmitted to an IC chip inside the LED lamp bead, and after receiving electric current containing the address information, the IC chip automatically decodes to generate a logical address consistent with the address information carried by the light. Further disclosed is a programming device, including an MUC chip, an optical signal encoding modulator, an amplifier circuit, a light source and a software input module.

### CROSS-REFERENCE TO RELATED APPLICATIONS

This application claims priority to Chinese Patent Application No. 202410673624.3, filed on May 28, 2024, which is hereby incorporated by reference in its entirety.

### TECHNICAL FIELD

The present disclosure relates to the field of LED lamp bead chips, and particularly relates to a method for obtaining different addresses by changing internal logic values of a chip through light.

### BACKGROUND

At present, chip programming is usually performed by using a burner, and a programmer is also required. In the process of programming, a chip to be programmed must be correctly installed into a socket or a fixture of the programmer. Data verification is performed after programming is complete, and the chip is removed from the burner after confirming that the programming is successful. This commonly used chip programming method is a contact-based and multi-step process, which is relatively cumbersome and needs further improvement.

### SUMMARY

An objective of the present disclosure is to provide a method for obtaining different addresses by changing internal logic values of a chip through light, aiming to solve the problems that the traditional chip programming requires contact and involves various steps such as installation and disassembly, making the programming more cumbersome.

According to a first aspect of the present disclosure, a method for obtaining different addresses by changing internal logic values of a chip through light is provided, the light containing address information is irradiated on a LED lamp bead, and then is transmitted to an IC chip inside the LED lamp bead, and after receiving electric current containing the address information, the IC chip automatically decodes to generate a logical address consistent with the address information carried by the light.

According to a second aspect of the present disclosure, a programming device used for the method for obtaining different addresses by changing internal logic values of a chip through light is provided, the programming device includes an MUC chip, an optical signal encoding modulator, an amplifier circuit, a light source and a software input module, where the software input module is used for inputting a program for changing the internal logical values of the chip, the optical signal encoding modulator, the amplifier circuit and the software input module are all electrically connected to the MUC chip, the amplifier circuit is further electrically connected to the optical signal encoding modulator, and the optical signal encoding modulator is electrically connected to the light source; the MUC chip is used for extracting the program for changing the internal logical values of the chip inputted by the software input module, and transmitting the program to the optical signal encoding modulator; and the optical signal encoding modulator controls the light source to emit optical signals with a certain frequency according to the program for changing the internal logical values of the chip inputted by the software input module.

According to a third aspect of the present disclosure, an LED lamp bead is provided, the LED lamp bead includes the IC chip, and the logical address in the IC chip is obtained by using the foregoing method for obtaining different addresses by changing internal logic values of a chip through light.

Further, the LED lamp bead has three-primary-color light-emitting units, and the three-primary-color light-emitting units are an R light-emitting unit, a G light-emitting unit and a B light-emitting unit, respectively.

Further, the three-primary-color light-emitting units are all electrically connected to a VDD pin, and are then electrically connected to a positive electrode of the power supply through the VDD pin.

Further, the IC chip is electrically connected to a controller for controlling the LED lamp bead through a DIN pin, and the IC chip is further electrically connected to the positive and negative electrodes of the power supply through the VDD and a VSS pin, respectively.

Compared with the prior art, the programming device and the method for obtaining different addresses by changing internal logic values of a chip through light provided by the present disclosure can define an address of the IC chip through light containing the data information in a non-contact manner. Compared with the traditional chip programming, which requires contact and involves various steps such as installation and disassembly, the programming device has the advantages of simple programming step and high programming efficiency.

### BRIEF DESCRIPTION OF DRAWINGS

FIG. 1 is a block diagram of an electrical control structure of a programming device according to the present disclosure.

FIG. 2 is a structural schematic diagram of an LED lamp bead according to the present disclosure.

Reference numerals in the accompanying drawings: 1. IC chip; and 2. three-primary-color light-emitting unit.

### DETAILED DESCRIPTION OF THE EMBODIMENTS

In the present disclosure, unless otherwise explicitly specified and defined, the terms "mounting", "connecting", "connection", "fixing", etc. should be understood in a broad sense, for example, they may be a fixed connection, a detachable connection, or an integrated connection; may be a mechanical connection, or an electrical connection; may be a direct connection, or an indirect connection via an intermediate medium; and may be communication inside two elements, or an interactive relation between two elements. Those of ordinarily skilled in the art can understand specific meanings of the above terms in the present disclosure according to specific circumstances.

The present disclosure will be further described below in conjunction with the accompanying drawings and specific embodiments:

### Embodiment 1

This embodiment provides a method for obtaining different addresses by changing internal logic values of a chip through light, the light containing address information is irradiated on a LED lamp bead, and then is transmitted to an IC chip inside the LED lamp bead, and after receiving electric current containing the address information, the IC chip automatically decodes to generate a logical address consistent with the address information carried by the light.

The principle is as follows: in the initial state, all chip codes are the same, and all logic values are zero; and after being exposed to external light containing address information, the LED chip, after sensing the light, transmits the logic information to the chip by using the photosensitivity characteristics, such that the corresponding internal logic value of the chip is rewritten, and in this way, an purpose of reassigning a new address logic value to the LED light-emitting chip can be achieved.

### Embodiment 2

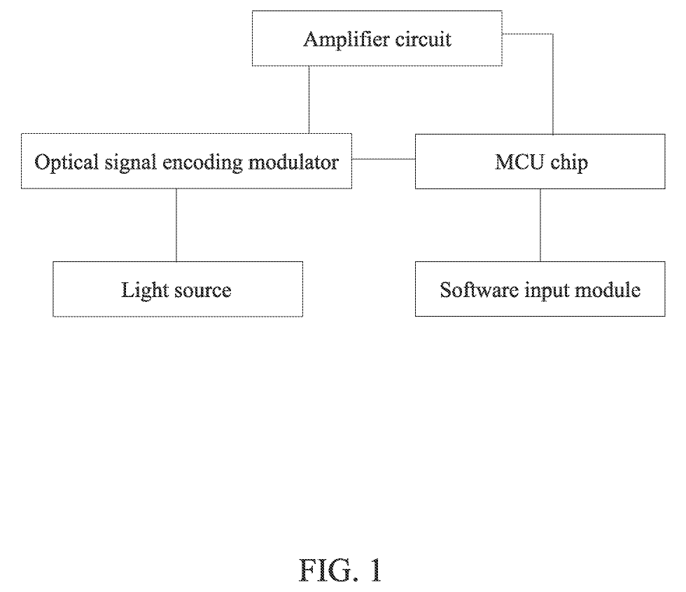

This embodiment provides a programming device, which is used for the method for obtaining different addresses by changing internal logic values of a chip through light provided in Embodiment 1. As shown in FIG. 1, the programming device includes an MUC chip, an optical signal encoding modulator, an amplifier circuit, a light source and a software input module, where the software input module is used for inputting a program for changing the internal logical values of the chip, the optical signal encoding modulator, the amplifier circuit and the software input module are all electrically connected to the MUC chip, the amplifier circuit is further electrically connected to the optical signal encoding modulator, and the optical signal encoding modulator is electrically connected to the light source. The MUC chip is used for extracting the program for changing the internal logical values of the chip inputted by the software input module, and transmitting the program to the optical signal encoding modulator, and the optical signal encoding modulator controls the light source to emit optical signals with a certain frequency according to the program for changing the internal logical values of the chip inputted by the software input module.

The programming device provided by the present disclosure can define an address of the IC chip through light containing the data information in a non-contact manner. Compared with the traditional chip programming, which requires contact and involves various steps such as installation and disassembly, the programming device has the advantages of simple programming step and high programming efficiency.

### Embodiment 3

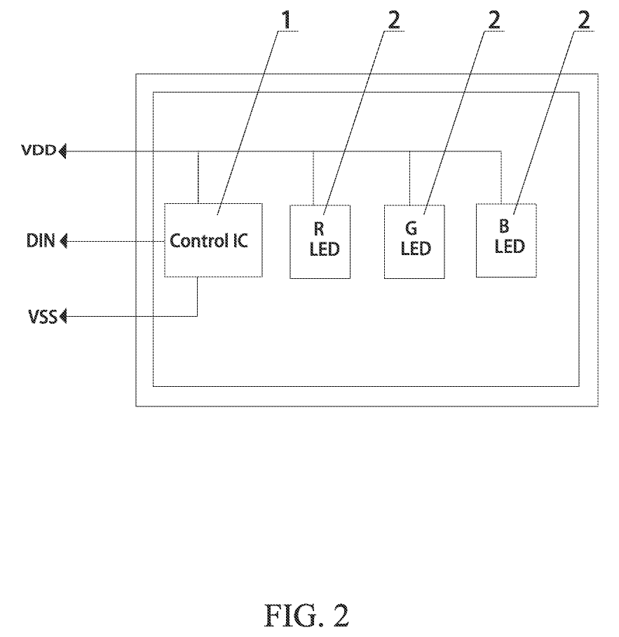

This embodiment provides an LED lamp bead, as shown in FIG. 2, the LED lamp bead includes the IC chip 1 and three-primary-color light-emitting units 2, and the logical address in the IC chip 1 is obtained by using the method for obtaining different addresses by changing internal logic values of a chip through light provided in Embodiment 1. The three-primary-color light-emitting units 2 are an R light-emitting unit, a G light-emitting unit and a B light-emitting unit, respectively, and the three-primary-color light-emitting units 2 are combined to form RGB light primary colors. The three-primary-color light-emitting units 2 are all electrically connected to a VDD pin, and are then electrically connected to a positive electrode of a power supply through the VDD pin. The IC chip 1 is electrically connected to a controller for controlling the LED lamp bead through a DIN pin, and the IC chip 1 is further electrically connected to the positive and negative electrodes of the power supply through the VDD and a VSS pin, respectively.

The above descriptions are only preferred embodiments of the present disclosure, and are not intended to be limiting of the present disclosure, and various changes and modifications may be made by those skilled in the art. Any modification, equivalent replacement, improvement, etc. made within the spirit and principle of the present disclosure shall fall within the protection scope of the present disclosure.

What is claimed is:

1. A method for obtaining different addresses by changing internal logic values of a chip through light, wherein the light containing address information is irradiated on a LED lamp bead, and then is transmitted to an IC chip inside the LED lamp bead, and after receiving electric current containing the address information, the IC chip automatically decodes to generate a logical address consistent with the address information carried by the light.

2. A programming device used for the method for obtaining different addresses by changing internal logic values of a chip through light according to claim 1, comprising an MUC chip, an optical signal encoding modulator, an amplifier circuit, a light source and a software input module, wherein the software input module is used for inputting a program for changing the internal logical values of the chip, the optical signal encoding modulator, the amplifier circuit and the software input module are all electrically connected to the MUC chip, the amplifier circuit is further electrically connected to the optical signal encoding modulator, and the optical signal encoding modulator is electrically connected to the light source; the MUC chip is used for extracting the program for changing the internal logical values of the chip inputted by the software input module, and transmitting the program to the optical signal encoding modulator; and the optical signal encoding modulator controls the light source to emit optical signals with a certain frequency according to the program for changing the internal logical values of the chip inputted by the software input module.

3. An LED lamp bead, comprising the IC chip, wherein the logical address in the IC chip is obtained by using the method for obtaining different addresses by changing internal logic values of a chip through light according to claim 1.

4. The LED lamp bead according to claim 3, wherein the LED lamp bead has three-primary-color light-emitting units, and the three-primary-color light-emitting units are an R light-emitting unit, a G light-emitting unit and a B light-emitting unit, respectively.

5. The LED lamp bead according to claim 4, wherein the three-primary-color light-emitting units are all electrically connected to a VDD pin, and are then electrically connected to a positive electrode of a power supply through the VDD pin.

6. The LED lamp bead according to claim 5, wherein the IC chip is electrically connected to a controller for controlling the LED lamp bead through a DIN pin, and the IC chip is further electrically connected to the positive and negative electrodes of the power supply through the VDD and a VSS pin, respectively.
